(19) United States
(12) Patent Application Publication
(10) Pub. No.: US 2025/0300425 A1
(43) Pub. Date: Sep. 25, 2025

(54) OPTICAL MODULE

(71) Applicant: SUMITOMO ELECTRIC DEVICE INNOVATIONS, INC., Yokohama-shi (JP)

(72) Inventors: Kuniyuki ISHII, Yokohama-shi (JP); Masanobu KAWAMURA, Yokohama-shi (JP); Hiroshi HARA, Yokohama-shi (JP); Shuuzo KIMURA, Yokohama-shi (JP)

(73) Assignee: SUMITOMO ELECTRIC DEVICE INNOVATIONS, INC., Yokohama-shi (JP)

(21) Appl. No.: 19/081,489

(22) Filed: Mar. 17, 2025

(30) Foreign Application Priority Data
Mar. 22, 2024 (JP) 2024-046970

(51) Int. Cl. H01S 5/024; H01S 5/02325

(52) U.S. Cl. CPC H01S 5/02453; H01S 5/02325; H01S 5/02461

(57) ABSTRACT

An optical module includes a semiconductor light-emitting element; a heat insulating material mechanically connected to the semiconductor light-emitting element on a first surface side of the heat insulating material and made of at least one of glass and ceramic; and a mounting portion which is located on a second surface side of the heat insulating material, and in which a region corresponding to an optical circuit unit of an optical circuit board is disposed. The second surface side faces opposite to the first surface side of the heat insulating material.

### CROSS REFERENCE

Priority is claimed on Japanese Patent Application No. 2024-046970, filed on Mar. 22, 2024, the entire content of which is incorporated herein by reference.

### TECHNICAL FIELD

The present disclosure relates to an optical module.

### BACKGROUND

Japanese Unexamined Patent Publication No. 2020-13831 discloses an optical module. The optical module includes a chip carrier on which a wavelength-tunable laser element that emits laser light and a temperature detection element are mounted; a photodetector that detects the laser light output from the wavelength-tunable laser element; a temperature control element on which the chip carrier and the photodetector are mounted; and a housing that houses the temperature control element and that includes a window portion that outputs the laser light.

### SUMMARY

An optical module according to one embodiment of the present disclosure includes a semiconductor light-emitting element; a heat insulating material mechanically connected to the semiconductor light-emitting element on a first surface side of the heat insulating material and made of at least one of glass and ceramic; and a mounting portion which is located on a second surface side of the heat insulating material, and in which a region corresponding to an optical circuit unit of an optical circuit board is disposed. The second surface side faces opposite to the first surface side of the heat insulating material.

### BRIEF DESCRIPTION OF THE DRAWINGS

FIG. 1 is a plan view showing an optical transceiver according to a first embodiment of the present disclosure.

FIG. 2 is a perspective view showing a peripheral structure of an optical module and a photonic IC.

FIG. 3 is a perspective view showing the peripheral structure of the optical module and the photonic IC.

FIG. 4 is a cutaway perspective view showing the optical module together with a housing provided in the optical transceiver.

FIG. 5 is a side cross-sectional view showing the optical module together with the housing.

FIG. 6 is a perspective view showing a configuration of the optical module when viewed from a heat insulating material.

FIG. 7 is a plan view showing the configuration of the optical module when viewed from the heat insulating material.

FIG. 8 is a side view of the optical module.

FIG. 9 is an enlarged schematic view showing a peripheral structure of a condenser lens and a light guide member.

FIG. 10 is a plan view showing an optical transceiver according to a second embodiment of the present disclosure.

FIG. 11 is an enlarged perspective view showing an optical module.

FIG. 12 is an enlarged perspective view showing the optical module.

### DETAILED DESCRIPTION

An optical transmitter or an optical transceiver (hereinafter, referred to as an optical transmitter or the like) used in optical communication includes, for example, a semiconductor light-emitting element such as a semiconductor laser element, and an optical modulation unit that modulates light emitted from the semiconductor light-emitting element. Generally, inside a housing for the optical transmitter and the like, the light emitted from the semiconductor light-emitting element is guided to the optical modulation unit by an optical fiber. Meanwhile, there is an increasing demand for miniaturization of the optical transmitter and the like. In a structure in which the optical fiber is built into the housing, it is difficult to miniaturize the optical transmitter and the like.

An object of the present disclosure is to provide an optical module that enables an optical transmitter and the like to be miniaturized.

### Description of Embodiment of Present Disclosure

Initially, the contents of an embodiment of the present disclosure will be listed and described.
[1] An optical module according to one embodiment of the present disclosure includes a semiconductor light-emitting element; a heat insulating material mechanically connected to the semiconductor light-emitting element on a first surface side of the heat insulating material and made of at least one of glass and ceramic; and a mounting portion which is located on a second surface side of the heat insulating material, and in which a region corresponding to an optical circuit unit of an optical circuit board is disposed. The second surface side faces opposite to the first surface side of the heat insulating material.
[2] The optical module according to the above [1] may further include a temperature control structure thermally connected to the semiconductor light-emitting element, and including a first plate, a second plate, and a Peltier element disposed between the first plate and the second plate.
[3] In the optical module according to the above [2], a surface of the temperature control structure on which the semiconductor light-emitting element is mounted faces the heat insulating material and is separated from the heat insulating material through a space.
[4] An optical module according to one embodiment of the present disclosure includes a heat insulating plate mechanically connected to a semiconductor light-emitting element on a first surface side of the heat insulating plate and made of at least one of glass and ceramic; a mounting portion which is located on a second surface side of the heat insulating plate in a region overlapping the semiconductor light-emitting element, and in which a region corresponding to an optical circuit unit of an optical circuit board is disposed; the optical circuit board disposed on the mounting portion; and an optical coupling portion that optically couples the semiconductor light-emitting element to the optical circuit board. The second surface side faces opposite to the first surface side of the heat insulating material.
[5] The optical module according to the above [4] may further include a temperature control structure thermally connected to the semiconductor light-emitting element, and including a first plate, a second plate, and a Peltier element disposed between the first plate and the second plate.
[6] In the optical module according to the above [5], the first plate of the temperature control structure may be coupled to the first surface side of the heat insulating plate in a face-to-face arrangement, and the semiconductor light-emitting element may be placed on a surface of the first plate opposite to the heat insulating plate.

### Details of Embodiment of Present Disclosure

Specific examples of the present disclosure will be described below with reference to the drawings. Incidentally, the present disclosure is not limited to the examples to be provided, and it is intended that the present disclosure includes all modifications defined by the claims and made within the concept and scope equivalent to the claims. In the following description, the same components in the description of the drawings are denoted by the same reference signs, and duplicate descriptions will not be repeated.

### First Embodiment

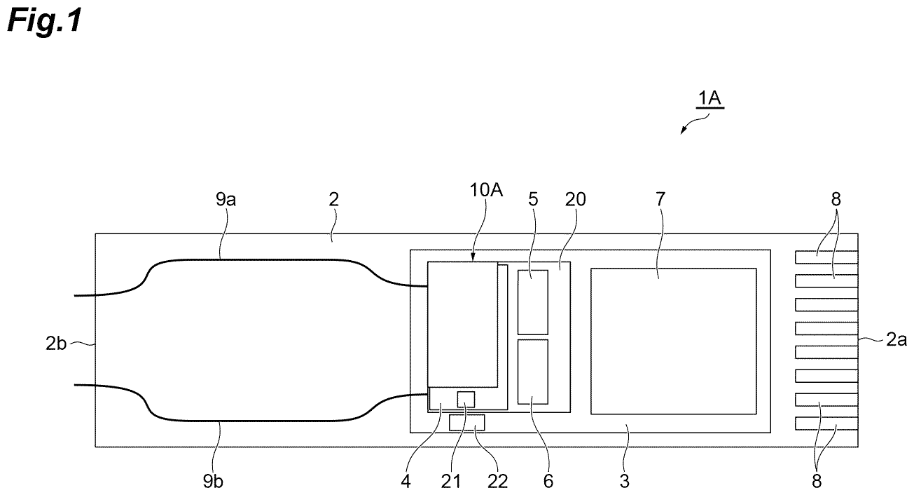

FIG. 1 is a plan view showing an optical transceiver 1A according to a first embodiment of the present disclosure. The optical transceiver 1A of the present embodiment includes an optical transmitter and an optical receiver. To this end, the optical transceiver 1A includes a substrate 2, a base 3, a laser diode driver (LDD) 5, a transimpedance amplifier (TIA) 6, a digital signal processor (DSP) 7, a plurality of terminals 8, an optical fiber 9a, an optical fiber 9b, an optical module 10A, and a photonic IC 20 (optical circuit board).

The substrate 2 is a plate-shaped member, and has, for example, a rectangular planar shape. The substrate 2 is made of, for example, resin. The plurality of terminals 8 are provided side by side along a first short side 2a of the substrate 2. The base 3 is disposed on the substrate 2, and is fixed to the substrate 2. The base 3 is a plate-shaped member, and has, for example, a rectangular planar shape. The constituent material of the base 3 is, for example, a glass epoxy laminate or a ceramic laminate. The optical fibers 9a and 9b are disposed near a second short side 2b opposite to the first short side 2a on the substrate 2. The optical fiber 9a outputs transmission light from the optical transmitter to the outside of the optical transceiver 1A. The optical fiber 9b inputs received light from outside the optical transceiver 1A to the optical receiver.

The photonic IC 20 is disposed in a region near the second short side 2b on the base 3. The photonic IC 20 is, for example, a device including an optical circuit unit in which an optical waveguide, a photodiode, an optical modulator, and the like are integrated on a silicon substrate or an InP substrate. One end of each of the optical fibers 9a and 9b is connected to the photonic IC 20. The photonic IC 20 inputs the transmission light, which is modulated by the optical modulator, to the optical fiber 9a. To this end, the photonic IC 20 includes an optical port for inputting unmodulated light to be input to the optical modulator. The photonic IC 20 may have a wavelength locking mechanism including an etalon filter. The photonic IC 20 converts the received light from the optical fiber 9b into a current signal using the photodiode.

The LDD 5 includes a built-in driver circuit for driving the optical modulator of the photonic IC 20. The TIA 6 converts the current signal output from the photodiode of the photonic IC 20 into a voltage signal. The LDD 5 and the TIA 6 are disposed side by side in a region near the first short side 2a on the base 3. Each of the LDD 5 and the TIA 6 is electrically connected to the corresponding terminal 8 among the plurality of terminals 8 via a wiring embedded in the substrate 2.

The DSP 7 includes a large-scale integrated circuit that drives the photonic IC 20 and that processes high-speed signals. The DSP 7 is disposed in a region near the first short side 2a on the base 3, and is aligned with the photonic IC 20 in a direction along the long side of the substrate 2. The DSP 7 is electrically connected to the corresponding terminal 8 among the plurality of terminals 8 via a wiring embedded in the substrate 2.

The optical module 10A inputs the unmodulated light to be input to the optical modulator to the optical port of the photonic IC 20. The optical module 10A is disposed in a region near the second short side 2b on the base 3, and is aligned with the LDD 5 and the TIA 6 in the direction along the long side of the substrate 2.

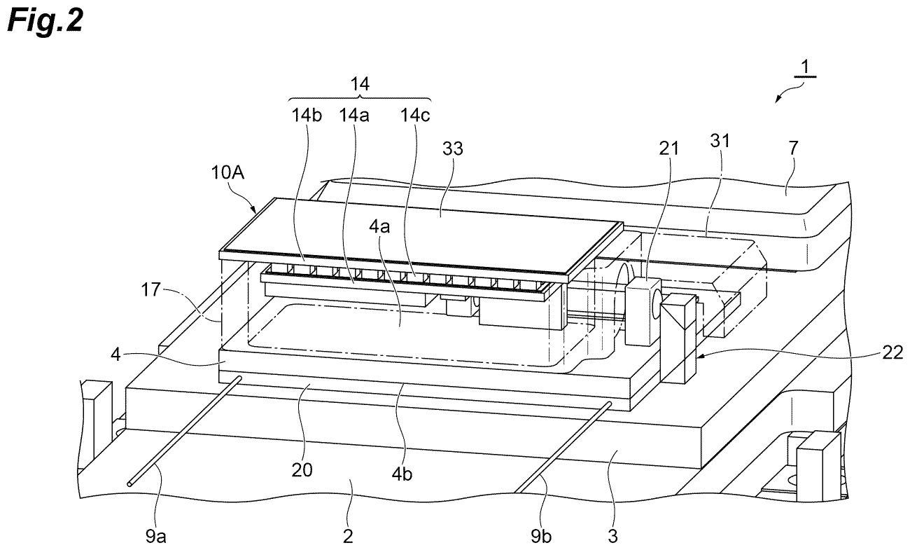

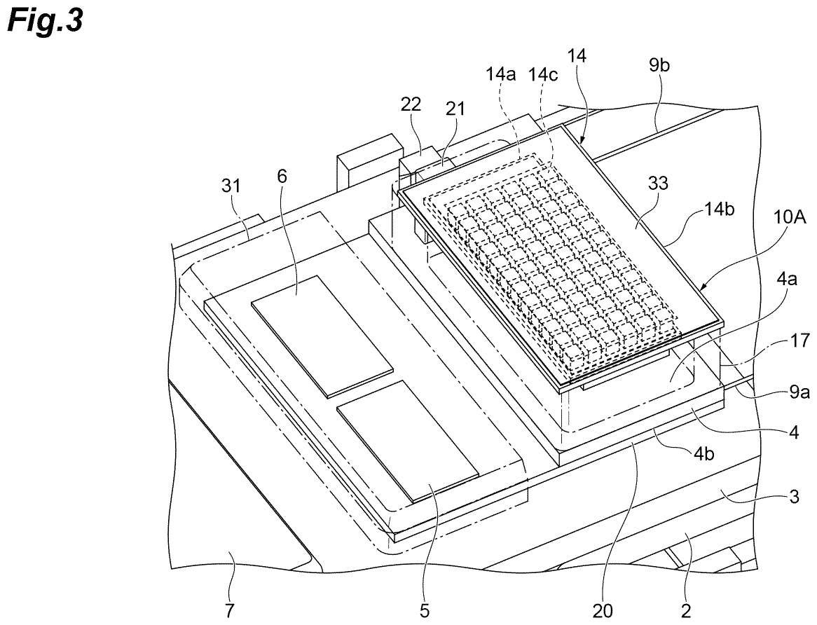

FIGS. 2 and 3 are perspective views showing a peripheral structure of the optical module 10A and the photonic IC 20. As shown in these figures, the LDD 5 and the TIA 6 are covered and protected by a cover 31 (shown by imaginary lines in the figures).

The optical module 10A includes a temperature control structure 14, a heat insulating material 4, and a support member 17. The temperature control structure 14 includes a first plate 14a and a second plate 14b facing each other. The first plate 14a and the second plate 14b are parallel to each other. Furthermore, the temperature control structure 14 includes a Peltier element 14c disposed between the first plate 14a and the second plate 14b. The Peltier element 14c transfers heat from the first plate 14a to the second plate 14b.

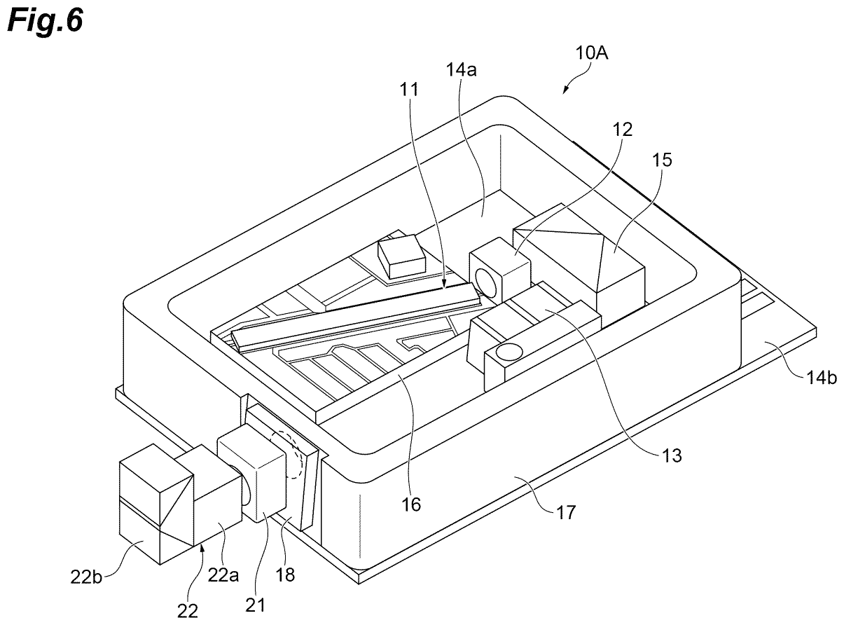

The heat insulating material 4 is a plate-shaped member, for example, a ceramic plate or a glass plate. The ceramic is, for example, alumina. A thermal conductivity of glass is approximately 1.0 W/mK, and a thermal conductivity of alumina is 2 to 3 W/mK. The heat insulating material 4 is disposed on a side opposite to the second plate 14b with respect to the first plate 14a. The heat insulating material 4 has a first surface 4a and a second surface 4b. The first surface 4a faces the first plate 14a of the temperature control structure 14. The second surface 4b faces away from the first surface 4a. In one example, the second surface 4b is parallel to the first surface 4a. The second surface 4b faces the photonic IC 20. In other words, the photonic IC 20 includes the optical circuit unit including the modulator, the waveguide, and the like, and is disposed on the second surface 4b of the heat insulating material 4 while facing a semiconductor light-emitting element 11 (refer to FIG. 6). Namely, the optical module 10A is located on a second surface 4b side of the heat insulating material 4, and includes a mounting portion in which a region corresponding to the optical circuit unit of the photonic IC 20 is disposed. The reason the heat insulating material 4 is provided is as follows. The optical circuit unit of the photonic IC 20 (optical circuit board) controls optical characteristics through electrical or thermal control of the refractive index. In the case of aiming at miniaturization by disposing the optical circuit unit so as to overlap the semiconductor light-emitting element 11, the semiconductor light-emitting element 11 and the photonic IC 20 are directly or indirectly mechanically connected to each other. With regard to thermal coupling caused thereby, the influence of heat generated by the photonic IC 20 on the semiconductor light-emitting element 11 or the influence of heat generated by the semiconductor light-emitting element 11 on the photonic IC 20 photonic IC 20 is not negligible. When the temperature control structure 14 (TEC) is disposed to control the temperature of the semiconductor light-emitting element 11, the temperature of the temperature control structure 14 affects the photonic IC 20, which is a risk.

Namely, the heat insulating material 4 has a platform for disposing the photonic IC 20. Accordingly, the transfer of heat generated from the photonic IC 20 to the semiconductor light-emitting element 11 can be suppressed. Therefore, a change in the temperature of the semiconductor light-emitting element 11 caused by the heat can be suppressed, and wavelength stability can be achieved. In addition to a tunable LD, a CW, an EML, or the like can be used for the semiconductor light-emitting element 11.

The support member 17 supports the heat insulating material 4 and the second plate 14b with a gap therebetween. The support member 17 may have a shape surrounding various optical components (to be described later) mounted on the first plate 14a. In this case, the optical components mounted on the first plate 14a are hermetically sealed by the heat insulating material 4, the second plate 14b, and the support member 17.

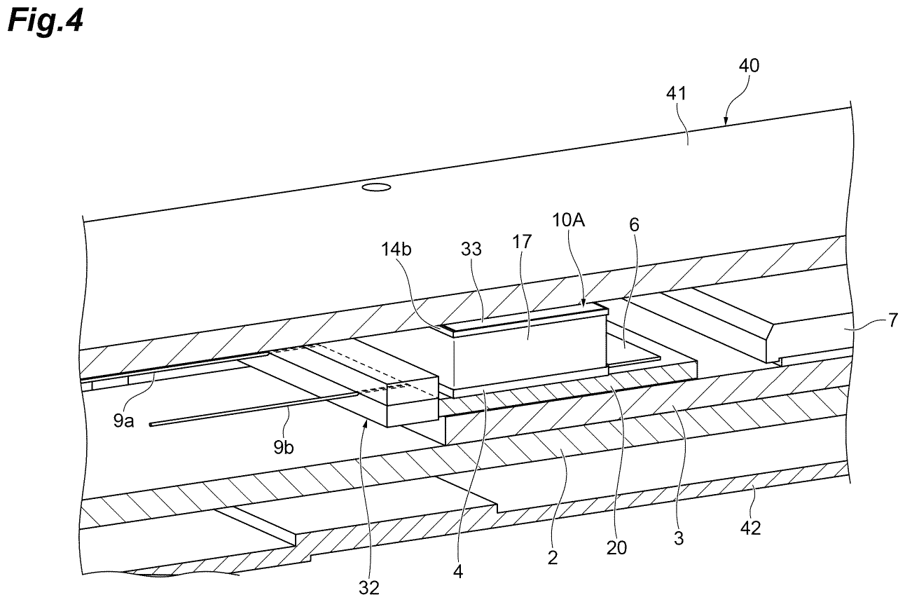

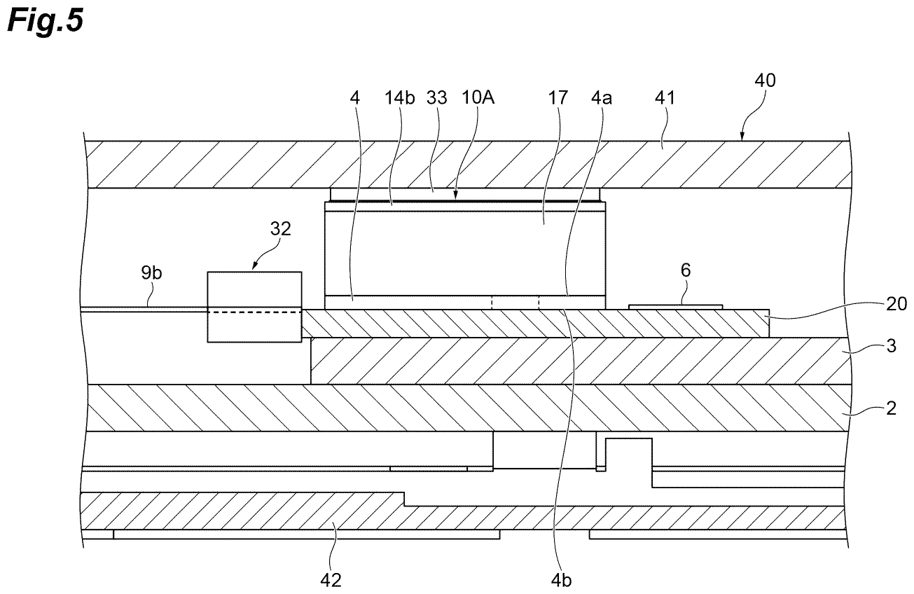

FIG. 4 is a cutaway perspective view showing the optical module 10A together with a housing 40 provided in the optical transceiver 1A. FIG. 5 is a side cross-sectional view showing the optical module 10A together with the housing 40. The housing 40 accommodates the substrate 2 and all the components disposed on the substrate 2 and including the optical module 10A and the photonic IC 20. The housing 40 includes a top plate 41 and a bottom plate 42. The optical transceiver 1A further includes a thermal interface material (TIM) 33 sandwiched between the top plate 41 of the housing 40 and the second plate 14b. As shown in the figure, the optical transceiver 1A may include a fiber holder 32 that clamps and holds end portions of the optical fibers 9a and 9b. The fiber holder 32 is fixed to a side surface of the photonic IC 20, so that the optical fibers 9a and 9b are connected to the photonic IC 20.

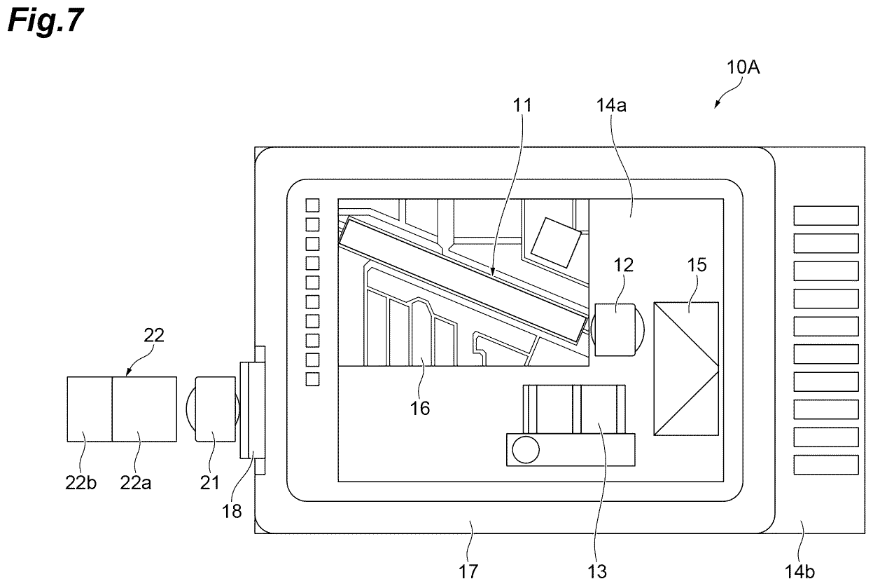

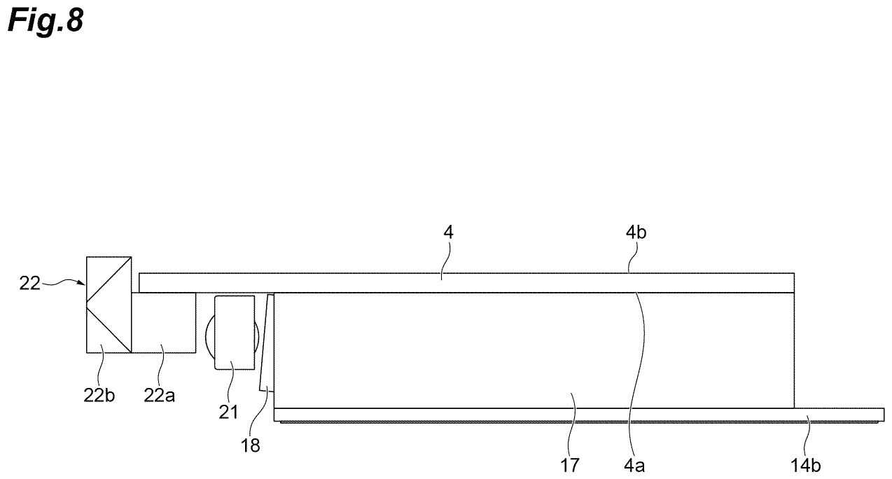

FIG. 6 is a perspective view showing a configuration of the optical module 10A when viewed from the heat insulating material 4. FIG. 7 is a plan view showing the configuration of the optical module 10A when viewed from the heat insulating material 4. In FIGS. 6 and 7, the heat insulating material 4 is not illustrated. FIG. 8 is a side view of the optical module 10A. As shown in these figures, the optical module 10A includes the semiconductor light-emitting element 11, a collimating lens 12, an isolator 13, a mirror member 15, a carrier 16, a condenser lens 21, and a light guide member 22. The semiconductor light-emitting element 11, the collimating lens 12, the isolator 13, the mirror member 15, and the carrier 16 are mounted on the first plate 14a, and are disposed between the first plate 14a and the heat insulating material 4.

The semiconductor light-emitting element 11 is mounted on the carrier 16, and is thermally connected to the first plate 14a via the carrier 16. A surface of the temperature control structure 14 on which the semiconductor light-emitting element 11 is placed is disposed to face the heat insulating material 4 with a gap between the surface and the heat insulating material 4, and has a space between the surface and the heat insulating material 4. The semiconductor light-emitting element 11 emits light in a direction intersecting a plate thickness direction of the first plate 14a. The semiconductor light-emitting element 11 is, for example, a semiconductor laser element, and the light emitted from the semiconductor light-emitting element 11 is, for example, laser light. The semiconductor laser element may be of a wavelength-tunable type or a continuous light emission type, or may be an electro-absorption modulator integrated laser diode (EML) in which an electro-absorption optical modulator is integrated. The temperature of the semiconductor light-emitting element 11 is controlled by the temperature control structure 14 described above such that the emission wavelength of the semiconductor light-emitting element 11 becomes a predetermined wavelength. The carrier 16 is provided with a plurality of wirings that are connected to the semiconductor light-emitting element 11.

The collimating lens 12 is mounted on the first plate 14a, and is optically coupled to the semiconductor light-emitting element 11. The collimating lens 12 collimates the light emitted from the semiconductor light-emitting element 11. The mirror member 15 is optically coupled to the semiconductor light-emitting element 11 via the collimating lens 12, and folds back an optical path of the light emitted from the semiconductor light-emitting element 11. The isolator 13 is optically coupled to the semiconductor light-emitting element 11 via the collimating lens 12 and the mirror member 15. The isolator 13 prevents the light emitted from the semiconductor light-emitting element 11 from returning to the semiconductor light-emitting element 11.

The condenser lens 21 and the light guide member 22 are disposed outside the first plate 14a and outside the support member 17 when viewed in the plate thickness direction of the first plate 14a. The condenser lens 21 is disposed on the first surface 4a of the heat insulating material 4, and is fixed to the first surface 4a. The condenser lens 21 is optically coupled to the isolator 13 through an opening formed in the support member 17. When the support member 17 hermetically seals the semiconductor light-emitting element 11, the collimating lens 12, and the isolator 13, a window material 18 for hermetically sealing the opening is provided in the opening of the support member 17. The light guide member 22 is optically coupled to the semiconductor light-emitting element 11 via the collimating lens 12, the mirror member 15, the isolator 13, and the condenser lens 21. The light guide member 22 is disposed side by side with the heat insulating material 4 in the direction intersecting the plate thickness direction of the first plate 14a (refer to FIG. 8). The light guide member 22 is fixed to the heat insulating material 4.

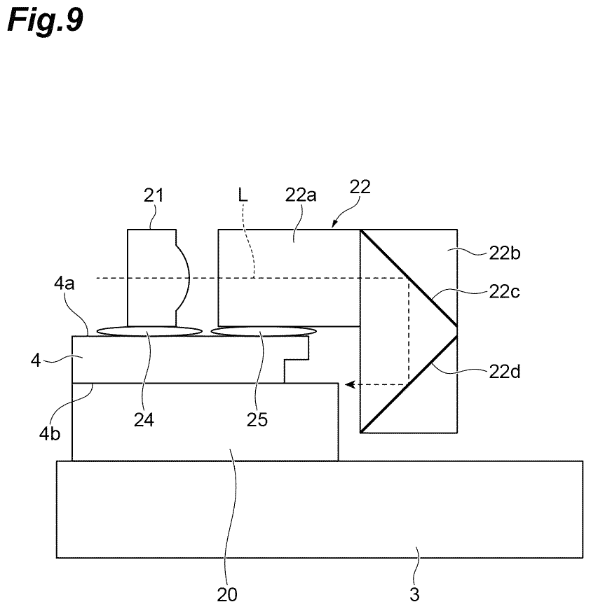

FIG. 9 is an enlarged schematic view showing a peripheral structure of the condenser lens 21 and the light guide member 22. The condenser lens 21 is disposed on an optical path between the isolator 13 and the light guide member 22. The condenser lens 21 is fixed to the first surface 4a of the heat insulating material 4 using an adhesive 24. The condenser lens 21 focuses light L, which is emitted from the semiconductor light-emitting element 11, toward the light guide member 22.

The light guide member 22 guides the light L, which has propagated above the first surface 4a of the heat insulating material 4, specifically, through a space between the first surface 4a and the first plate 14a, onto the second surface 4b of the heat insulating material 4. The light guide member 22 of the present embodiment includes a first portion 22a and a second portion 22b. The first portion 22a protrudes above the first surface 4a of the heat insulating material 4, and is fixed to the first surface 4a of the heat insulating material 4 using by an adhesive 25. The second portion 22b is provided integrally with the first portion 22a, and is aligned with the heat insulating material 4 in the direction intersecting the plate thickness direction of the first plate 14a. The second portion 22b includes a first mirror 22c and a second mirror 22d. The first mirror 22c reflects the light L, which has propagated above the first surface 4a, in a thickness direction of the heat insulating material 4. The second mirror 22d reflects the light L reflected by the first mirror 22c toward the photonic IC 20 on the second surface 4b. The photonic IC 20 receives the light L guided by the light guide member 22, and modulates the light L. The second portion 22b is, for example, a member transparent to the wavelength of the light L, and is a prism including the first mirror 22c and the second mirror 22d that reflect the light L.

Effects obtained by the optical transceiver 1A and the optical module 10A of the present embodiment described above will be described. In the optical module 10A, since the semiconductor light-emitting element 11 is mounted on the first plate 14a of the temperature control structure 14, and the first plate 14a is located on the heat insulating material 4, the transfer of heat generated in the photonic IC 20 to the semiconductor light-emitting element 11 is suppressed, and the temperature of the semiconductor light-emitting element 11 can be suitably controlled. In addition, the light L emitted from the semiconductor light-emitting element 11 is guided by the light guide member 22 from above the first surface 4a to above the second surface 4b of the heat insulating material 4. As in the present embodiment, an optical component such as the photonic IC 20 serving as an optical modulation unit can be disposed on the second surface 4b of the heat insulating material 4. Therefore, according to the optical module 10A of the present embodiment, since there is no need to use an optical fiber when the light L emitted from the semiconductor light-emitting element 11 is guided to the optical modulation unit, the optical transceiver 1A can be miniaturized.

As in the present embodiment, the heat insulating material 4 may be a glass plate. Glass has higher thermal insulation properties compared to ceramics. Therefore, in this case, the transfer of heat generated in the photonic IC 20 to the semiconductor light-emitting element 11 can be effectively suppressed.

As in the present embodiment, the optical module 10A may include the condenser lens 21 that is disposed outside the first plate 14a when viewed in the plate thickness direction of the first plate 14a, and that focuses the light L emitted from the semiconductor light-emitting element 11 toward the light guide member 22. In this case, the light L emitted from the semiconductor light-emitting element 11 is allowed to be efficiently incident on the light guide member 22.

As in the present embodiment, the light guide member 22 may be fixed to the heat insulating

material 4. In this case, the light guide member 22 and other members, for example, the semiconductor light-emitting element 11, the temperature control structure 14, and the like, can be easily integrated.

As in the present embodiment, the light guide member 22 may include the first mirror 22c that reflects the light L, which has propagated above the first surface 4a, in the thickness direction of the heat insulating material 4, and the second mirror 22d that reflects the light L reflected by the first mirror 22c to above the second surface 4b. In this case, the light L emitted from the semiconductor light-emitting element 11 can be suitably guided from above the first surface 4a to above the second surface 4b of the heat insulating material 4.

The optical transmitter of the present embodiment includes the optical module 10A and the photonic IC 20 that is disposed on the second surface 4b of the heat insulating material 4, and that receives the light L guided by the light guide member 22 and modulates the light L. Since the optical transmitter includes the optical module 10A, the optical transmitter can be miniaturized.

As in the present embodiment, the optical transmitter may include the housing 40 that accommodates the optical module 10A, and the thermal interface material 33 sandwiched between the second plate 14b and the housing 40. In this case, heat generated in the semiconductor light-emitting element 11 can be efficiently dissipated to the housing 40 through the temperature control structure 14.

As in the present embodiment, the optical transceiver 1A includes the optical transmitter including the optical module 10A, and the optical receiver. Since the optical transceiver 1A includes the optical transmitter including the optical module 10A, the optical transceiver 1A can be miniaturized.

### Second Embodiment

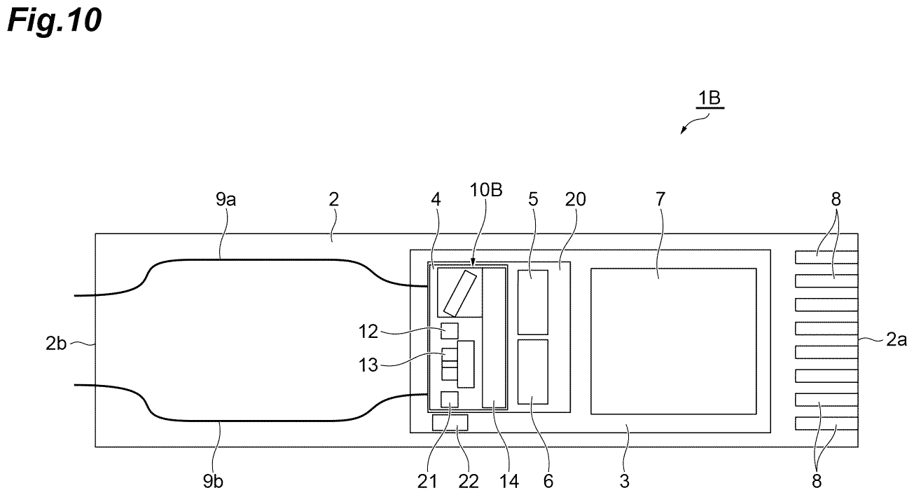

FIG. 10 is a plan view showing an optical transceiver 1B according to a second embodiment of the present disclosure. The optical transceiver 1B of the present embodiment includes an optical module 10B instead of the optical module 10A of the first embodiment. The other configuration of the optical transceiver 1B is the same as that of the optical transceiver 1A.

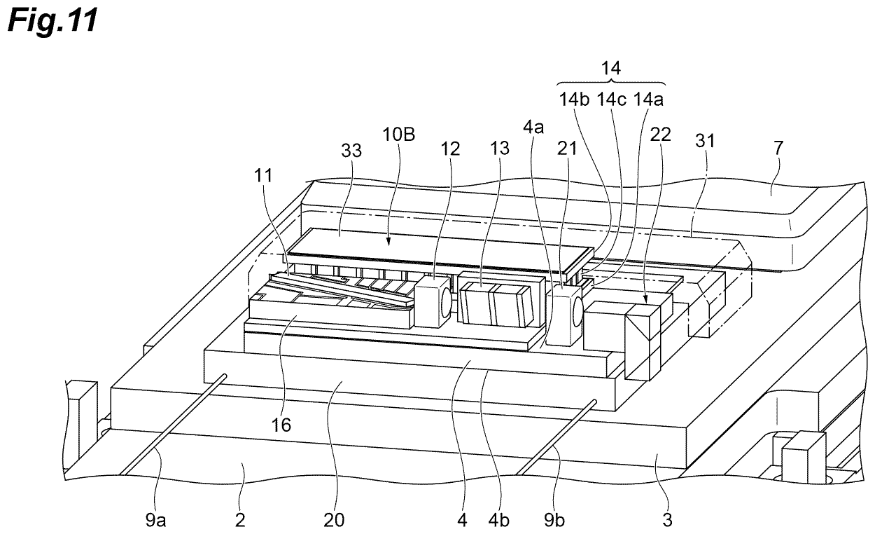

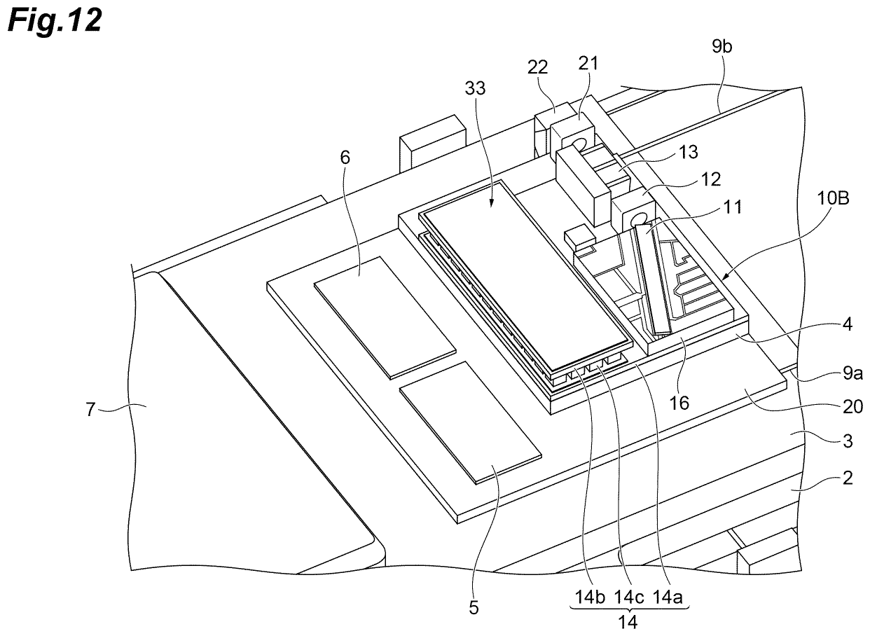

FIGS. 11 and 12 are enlarged perspective views showing the optical module 10B. The optical module 10B inputs unmodulated light to be input to the optical modulator to the optical port of the photonic IC 20. The optical module 10B is disposed in a region near the second short side 2b on the base 3, and is aligned with the LDD 5 and the TIA 6 in the direction along the long side of the substrate 2.

The optical module 10B includes the heat insulating material 4 (heat insulating plate), the semiconductor light-emitting element 11, the collimating lens 12, the isolator 13, and the temperature control structure 14. As in the first embodiment, the heat insulating material 4 is a plate-shaped member, for example, a ceramic plate or a glass plate. The heat insulating material 4 has the first surface 4a and the second surface 4b. The second surface 4b faces away from the first surface 4a. In one example, the second surface 4b is parallel to the first surface 4a. The second surface 4b faces the photonic IC 20. In other words, the photonic IC 20 is disposed on the second surface 4b of the heat insulating material 4.

The temperature control structure 14 includes the first plate 14a and the second plate 14b facing each other. The first plate 14a and the second plate 14b are parallel to each other. Furthermore, the temperature control structure 14 includes the Peltier element 14c disposed between the first plate 14a and the second plate 14b. The Peltier element 14c transfers heat from the first plate 14a to the second plate 14b. The first plate 14a is provided on the first surface 4a of the heat insulating material 4. Namely, the first plate 14a is coupled to the heat insulating material 4 in a face-to-face arrangement. Furthermore, the first plate 14a has a region aligned with the Peltier element 14c in the direction along the long side of the substrate 2.

The semiconductor light-emitting element 11 is placed on the surface of the first plate 14a opposite to the heat insulating material 4, and is mounted on the region of the first plate 14a, the region being aligned with the Peltier element 14c. In the illustrated example, the semiconductor light-emitting element 11 is mounted on the carrier 16 provided on the region of the first plate 14a. The semiconductor light-emitting element 11 emits light in the direction intersecting the plate thickness direction of the first plate 14a.

The collimating lens 12 is mounted on the first plate 14a, and is optically coupled to the semiconductor light-emitting element 11. The collimating lens 12 collimates the light emitted from the semiconductor light-emitting element 11. The isolator 13 is optically coupled to the semiconductor light-emitting element 11 via the collimating lens 12. The isolator 13 prevents the light emitted from the semiconductor light-emitting element 11 from returning to the semiconductor light-emitting element 11.

The optical module 10B further includes the condenser lens 21 and the light guide member 22. As in the first embodiment, the light guide member 22 is disposed side by side with the heat insulating material 4 in the direction intersecting the plate thickness direction of the first plate 14a. The light guide member 22 is optically coupled to the semiconductor light-emitting element 11, and guides the light, which has propagated above the first surface 4a of the heat insulating material 4, to above the second surface 4b of the heat insulating material 4. The detailed configurations of the condenser lens 21 and the light guide member 22 are the same as those in the first embodiment.

In the optical module 10B of the present embodiment, the semiconductor light-emitting element 11 is mounted on the first plate 14a of the temperature control structure 14, and the first plate 14a is located on the heat insulating material 4. Accordingly, the transfer of heat generated in the photonic IC 20 to the semiconductor light-emitting element 11 is suppressed, and the temperature of the semiconductor light-emitting element 11 can be suitably controlled. In addition, the light emitted from the semiconductor light-emitting element 11 is guided by the light guide member 22 from above the first surface 4a to above the second surface 4b of the heat insulating material 4. An optical component such as the photonic IC 20 serving as an optical modulation unit can be disposed on the second surface 4b of the heat insulating material 4. Therefore, according to the optical module 10B of the present embodiment, since there is no need to use an optical fiber when the light emitted from the semiconductor light-emitting element 11 is guided to the optical modulation unit, the optical transceiver can be miniaturized.

The optical module according to the present disclosure is not limited to the embodiments described above, and other various modifications can be made. For example, in the above-described embodiments, an example in which the photonic IC 20 is disposed on the second surface 4b of the heat insulating material 4, and the light guided by the light guide member 22 is incident on the photonic IC 20 has been provided. The component disposed on the second surface 4b of the heat insulating material 4 is not limited to the photonic IC 20. It is also possible to employ a grating coupler method in which a hole is formed in the heat insulating material 4 to couple light from the semiconductor light-emitting element 11 to the optical waveguide formed on the photonic IC 20.

In the above-described embodiments, an example in which the light guide member 22 includes the first mirror 22c and the second mirror 22d has been provided. As long as the light guide member can guide light from above the first surface 4a to above the second surface 4b of the heat insulating material 4, the configuration of the light guide member is not limited thereto.

What is claimed is:

1. An optical module, comprising:
a semiconductor light-emitting element;
a heat insulating material mechanically connected to the semiconductor light-emitting element on a first surface side of the heat insulating material and made of at least one of glass and ceramic; and
a mounting portion which is located on a second surface side of the heat insulating material, and in which a region corresponding to an optical circuit unit of an optical circuit board is disposed,
wherein the second surface side faces opposite to the first surface side of the heat insulating material.

2. The optical module according to claim 1, further comprising:
a temperature control structure thermally connected to the semiconductor light-emitting element, and including a first plate, a second plate, and a Peltier element disposed between the first plate and the second plate.

3. The optical module according to claim 2,
wherein a surface of the temperature control structure on which the semiconductor light-emitting element is mounted faces the heat insulating material and is separated from the heat insulating material through a space.

4. An optical module, comprising:
a heat insulating plate mechanically connected to a semiconductor light-emitting element on a first surface side of the heat insulating plate and made of at least one of glass and ceramic;
a mounting portion which is located on a second surface side of the heat insulating plate in a region overlapping the semiconductor light-emitting element, and in which a region corresponding to an optical circuit unit of an optical circuit board is disposed;
the optical circuit board disposed on the mounting portion; and
an optical coupling portion that optically couples the semiconductor light-emitting element to the optical circuit board,
wherein the second surface side faces opposite to the first surface side of the heat insulating material.

5. The optical module according to claim 4, further comprising:
a temperature control structure thermally connected to the semiconductor light-emitting element, and including a first plate, a second plate, and a Peltier element disposed between the first plate and the second plate.

6. The optical module according to claim 5,
wherein the first plate of the temperature control structure is coupled to the first surface side of the heat insulating plate in a face-to-face arrangement, and
the semiconductor light-emitting element is placed on a surface of the first plate opposite to the heat insulating plate.
